(19) United States
(12) Patent Application Publication
(10) Pub. No.: US 2022/0107280 A1
(43) Pub. Date: Apr. 7, 2022

(54) Defect Inspection Device and Defect Inspection Method

(71) Applicant: Hitachi High-Tech Corporation, Minato-ku, Tokyo (JP)

(72) Inventors: Kentaro OHIRA, Tokyo (JP); Masaki HASEGAWA, Tokyo (JP)

(21) Appl. No.: 17/296,828

(22) PCT Filed: Feb. 15, 2019
(86) PCT No.: PCT/JP2019/005469

§ 371 Date: Dec. 21, 2021

(51) Int. Cl. G01N 23/2251

(52) U.S. Cl. CPC G01N 23/2251; G01N 2223/309; G01N 2223/646; G01N 2223/418

(57) ABSTRACT

Provided is a quantification method for evaluating the quality of a sample on the basis of a mirror electron image acquired by a mirror electron microscope. In this invention, a mirror electron image is expressed numerically through counting of the brightness values of each pixel composing the mirror electron image, the creation of a brightness histogram, and the calculation, from the distribution of the brightness histogram, of a standard deviation. If brightness contrast is formed on the mirror electron image by, for example, a scratch on or latent damage in a sample, because the brightness values of the pixels will fluctuate, there will be more variation in the brightness values than in an image obtained from a satisfactory sample with no defects, and this will result in the brightness values of the mirror electron image having a larger standard deviation. The standard deviation indicates the variation in the brightness calculated from the mirror electron image and essentially represents the degree of defect contrast in the sample. This value can be used as a basis for simply evaluating the quality of a sample while eliminating subjectivity and ambiguity.

### TECHNICAL FIELD

The present invention relates to a defect inspection device that inspects surfaces of wafers for manufacturing electronic devices, and a method therefor.

### BACKGROUND ART

In semiconductor-device manufacturing, micro circuits are formed on a semiconductor wafer that is polished to have a mirror surface. If there is a foreign matter, a damage (scratch), a crystal defect, a damaged layer of a crystal or the like on such a wafer, a defect or a material deterioration occurs in the processes of the formation of a circuit pattern. Accordingly, a manufactured device becomes unable to operate normally or the operation reliability of the manufactured device deteriorates, thereby resulting in incompletion of a product.

Examples of such cases include a problem in power-device manufacturing that uses SiC (silicon carbide), which is a promising semiconductor material expected to reduce energy consumption. SiC excels in various characteristics as a power device material such as dielectric breakdown voltage as compared to Si, which is a conventionally used semiconductor, but SiC is a material which is more difficult to machine and polish into a wafer shape because it excels in chemical stability, and is hard. Devices are created on a SiC epitaxial layer formed on a polished surface. The formation of a high-quality epitaxial layer, which is essential for devices to attain reliability, requires removal of crystal disturbance (damaged layer) on the polished surface.

Wafers are flattened by mechanical polishing such as grinding. CMP (chemical mechanical polishing) is performed further to eliminate a damaged layer having occurred during the mechanical polishing, to thereby create a surface that is flat at the atomic level, and is free of crystal disturbance. However, it is difficult to set optimum time for the CMP process. Accordingly, damaged regions having occurred in the mechanical polishing remain inside the surface, or micro-scale scratches are formed in some cases. In particular, in a case that the surfaces of the remaining damaged regions are flat, or in a case that the widths of scratches are sufficiently small as compared to an emission wavelength, they cannot be found by a conventional optical inspection technology to detect concavities and convexities of the surfaces, and such damaged regions or scratch are called “latent damages.”

If an epitaxial layer is grown on a wafer surface having remaining latent damages and scratches, these become the starting points of abnormalities that occur at atomic steps, and structures with large concavities and convexities called step bunches are formed. If a device is formed on a surface having a step bunch having occurred thereon, the breakdown voltage characteristics deteriorate significantly, and so the device cannot be used as a power device. Accordingly, an inspection as to whether or not there are remaining latent damages or scratches is extremely important.

Patent Literature 1 discloses that, as an inspection technology sensitive to latent damages and scratches on a wafer surface, it is effective to use an inspection technology to which a mirror electron microscope that forms an image of mirror electrons is applied. In this inspection technology, a negative voltage close to an acceleration voltage of an emitted electron beam is applied to a wafer surface to thereby invert the electron beam direction near the wafer surface, the electrons illuminate over the entire inspection field of view on the wafer surface, form an image of the inverted electrons by electron lenses for inspection. These inverted electrons are referred to as mirror electrons, hereinafter.

In a defect inspection device using a mirror electron microscope, an ultraviolet ray is emitted simultaneously onto a wafer, and the wafer surface is excited by the ultraviolet ray illumination. This excitation energy causes electric charges inside the wafer to be captured by a damaged region section, and locally charged to distort the equipotential surface of the surface, but because in the imaging with the mirror electron microscope, even a slight distortion on the equipotential surface generates shading in a mirror electron image, and so it becomes possible to perform detection of a damaged region at high sensitivity. In addition, because an electron optical system is used in the image-formation, the resolution of the microscope is several dozen nanometers, which is far higher than in optical inspection technologies.

### CITATION LIST

### Patent Literature

Patent Literature 1: WO2016002003 A1

### SUMMARY OF INVENTION

### Technical Problem

A mirror electron microscope has an electron irradiation area of around 100 μmϕ, which is small as compared with the surface area of a wafer, and if the entire surface of a wafer with the size of six inches is inspected, for example, the inspection takes several weeks. Because of this, it is difficult to inspect the entire surface of a wafer with a mirror electron microscope, and a partial region in a wafer is inspected, defects are detected in an obtained mirror electron image, and the quality of the wafer is evaluated.

An output of a mirror electron microscope as inspection results is gray-scale images imaging the surface states of certain locations of a wafer. A user visually checks mirror electron images obtained from a plurality of locations in the wafer surface, and determines whether the quality of the wafer itself is good or bad. However, there is a problem that results of the visual evaluation of mirror electron images vary depending on subjectivity and ambiguity that vary depending on users, and the stability of inspection quality is affected.

An object of the present invention is to solve the problem mentioned above, and is to provide a defect inspection device and method that make it possible to attempt to quantify mirror electron images, and maintain the inspection quality.

### Solution to Problem

To achieve the goal described above, it is necessary to provide a user with results of quantification of mirror electron images output by a mirror electron microscope. The present invention provides an inspection device and an inspection method that quantify the degree of gray-scale contrast formed on mirror electron images due to latent damages, scratches, stacking faults, basal plane dislocation and foreign matters, and display the quantified degree. The present invention provides a defect inspection device including: an electron optical system that irradiates a sample with electrons emitted from an electron source; an imaging electron optical system that forms an image of mirror electrons reflected before the electrons reach the sample surface due to application of a negative voltage to the sample, and acquires a mirror electron image; an ultraviolet-ray emitting section that irradiates a range including an irradiation range of the electrons with an ultraviolet ray during the irradiation with the electrons;

an image processing device that performs a calculation process on the acquired mirror electron image, and outputs a result of the calculation; and a display device. The image processing device converts the mirror electron image into brightness values, and generates a reference, and an inspection result, and the display device displays the reference and the inspection result together. The present invention also provides a defect inspection method.

### Advantageous Effects of Invention

By not only outputting a mirror electron image of the mirror electron microscope, but converting the mirror electron image into brightness values, and displaying a reference, and an inspection result of an inspected sample together, it becomes easier for a user to quantitatively judge the quality of the sample relative to the reference.

In addition, by generating a histogram of the brightness of the mirror electron image of the inspected sample, and displaying the histogram and a reference histogram together, the user can efficiently judge the degree of the occurrence of defects in the inspected sample, and defect types that have occurred in larger amounts, from the degree of deviation from the reference.

Furthermore, by performing a statistical process such as standard deviation or variance on the brightness histograms of the reference and the mirror electron image of the inspected target sample, it is possible to more strictly compare the degree of the occurrence on the inspected sample relative to the reference. Thereby, variations of results as to qualities resulting from subjectivity and ambiguity that vary depending on users can be eliminated, and it becomes possible to stably judge whether the qualities of samples are good or bad.

### BRIEF DESCRIPTION OF DRAWINGS

FIG. 1 is a figure for explaining a mirror electron microscope device according to a first embodiment.

FIG. 2 is a figure illustrating a flow of quantifying a mirror electron image according to the first embodiment.

FIG. 3A is a figure for explaining an inspection method and a quantification method performed by the mirror electron microscope according to the first embodiment.

FIG. 3B is a figure for explaining the inspection method and the quantification method performed by the mirror electron microscope according to the first embodiment.

FIG. 3C is a figure for explaining the inspection method and the quantification method performed by the mirror electron microscope according to the first embodiment.

FIG. 4 is a figure for explaining wide-range imaging and a display method for the mirror electron image according to a fourth embodiment.

### DESCRIPTION OF EMBODIMENTS

In the following, embodiments of the present invention are explained sequentially in accordance with the drawings.

### First Embodiment

A first embodiment is an embodiment of a defect inspection device including: an electron optical system that irradiates a sample with electrons emitted from an electron source; an imaging electron optical system that forms an image of mirror electrons reflected before the electrons reach the sample due to application of a negative voltage to the sample, and acquires a mirror electron image; an ultraviolet-ray emitting section that irradiates a range including an irradiation range of the electrons with an ultraviolet ray during the irradiation of the electrons; and an image processing device that performs a calculation process on the acquired mirror electron image, and outputs a result of the calculation. The image processing device converts brightness values of the FOV (Field of View)-unit mirror electron image obtained from a plurality of locations on a sample surface, and outputs a predetermined reference (reference), and an inspection result of the sample. Note that the FOV-unit mirror electron image means a mirror electron image obtained from one inspection field of view. For example, it is supposed that an FOV-unit mirror electron image obtained in an electron irradiation area of 110 μmϕ is approximately 80 μm×80 μm.

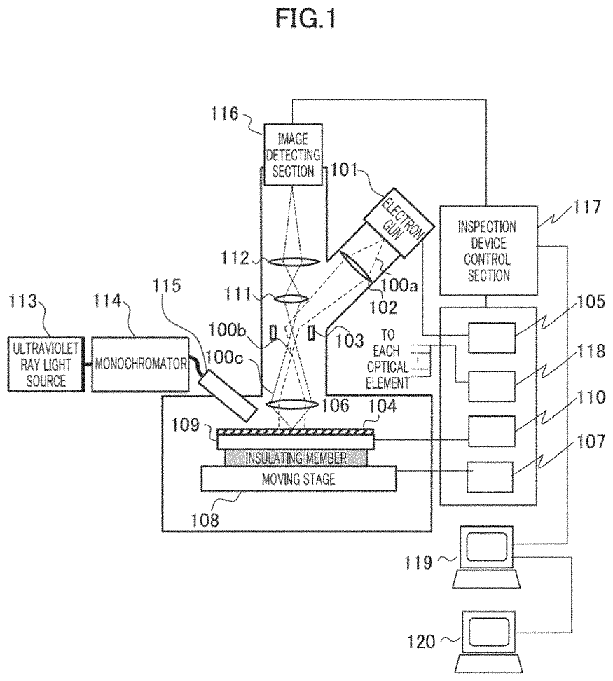

The whole of an inspection device using a mirror electron microscope according to the present invention is explained by using FIG. 1. It should be noted however that a pump for evacuation, a control device therefor, exhaust lines, a loading system for inspected samples, and the like are omitted. In addition, the trajectories of electrons are exaggerated as compared to actual trajectories for the sake of explanation.

First, the electron optical system for emitting electrons is explained. While being focused by a condenser lens 102, emitted electrons 100a from an electron gun 101 are deflected by a separator 103 to a wafer 104, and turn into approximately parallel electron flux and irradiate the wafer 104 of an inspection target.

While a Zr/O/W-type Schottky electron source that has a small light source diameter, and can produce a large current value is used as the electron gun 101, electron sources such as a LaB₆ electron source that can produce a higher current value or a cold cathode electron source that can provide higher brightness may also be used. In addition, the electron gun 101 may be a magnetic-field immersion type electron gun in which a magnetic lens is disposed near an electron source. Voltages and currents necessary for operation of the electron gun such as an extraction voltage of the electron gun 101, an acceleration voltage of an extracted electrons, or a heating current of an electron source filament are supplied and controlled by an electron-gun control device 105. In a case that a Schottky electron source or a cold cathode electron source is used for the electron source, the inside of the electron gun 101 needs to be maintained at an ultrahigh vacuum like 10⁻⁶ Pa or lower, and so is provided with a vacuum shield valve for maintaining the vacuum at the time of maintenance, and so on.

While the condenser lens 102 is drawn as a single lens in FIG. 1, it may instead by an electron optical system formed by combining a plurality of lens or multipoles such that an illumination electrons with a higher degree of parallelism are obtained. The condenser lens 102 is adjusted such that electrons are focused onto a back focal plane 100b of an objective lens 106. The objective lens 106 is an electrostatic lens including a plurality of electrodes, or a magnetic lens.

The separator 103 is installed for separating emitted electrons proceeding toward an inspected sample 104, and mirror electrons returning from the inspected sample 104. In the present embodiment, a separator using an E×B deflector is used. The E×B deflector can be set such that an electron coming from above is deflected, and an electron coming from below directs upward. In this case, the electron optical column that supplies illuminating electrons as in the figure is inclined, and the electron optical column that forms an image of mirror electrons is placed upright. In addition, it is also possible to use a deflector using only a magnetic field as the separator. A magnetic field is applied in a direction perpendicular to the optical axis, illumination electrons are deflected toward the inspected sample 104, and electrons from the inspected sample 104 are deflected in a direction directly opposite to the incoming direction of the illumination electrons. In this case, the optical axis of the electron optical column, and the optical axis of the electron imaging column are arranged to be symmetrical about the optical axis of the objective lens.

In a case that it is necessary to correct aberrations that occur when the illumination electrons 100a are deflected by the separator, an aberration corrector may be arranged additionally. In addition, in a case that the separator 403 is a magnetic field deflector, supplementary coils are provided to correct the aberrations.

The objective lens 106 shapes the illumination electrons 100a deflected by the separator 103 into a parallel electron beam bundle that illuminates the surface of the inspected sample 104 in a direction perpendicular to the surface. Because the condenser lens 102 in the illumination optic is adjusted such that the electrons are focused onto the back focal point 100b of the objective lens 106 as mentioned before, electrons with a high degree of parallelism can be illuminated onto the inspected sample 104. A region on the inspected sample 104 onto which the electrons 100a illuminate has an area of equal to 10000 μm² or the like, for example. The objective lens 106 includes an anode for pulling up mirror electrons upward above the surface of the inspected sample 104.

Next, the sample 104, and a stage section that holds the sample 104 are explained. A sample holder 109 is installed, via an insulating member, on a moving stage 108 controlled by a moving-stage control device 107, and the inspected sample 104 is placed on the sample holder 109. The method of driving of the moving stage 108 involves two orthogonal straight movements. In addition to this, a vertical movement, and movements in inclined directions may be added. With these movements, the moving stage 108 moves a position in the entire surface or discrete areas of the surface of the inspected sample 104 onto the irradiation position of the electron beam bundle, that is, onto the optical axis of the objective lens 106.

In order to form a negative potential on the surface of the inspected sample 104, a negative potential which is almost equal to the acceleration voltage of the electrons is supplied to the sample holder 109 by a high-voltage power supply 110. The output power of the high-voltage power supply 110 is finely adjusted such that the illumination electrons 100a are decelerated before the inspected sample 104 due to the negative potential, and the electron trajectories are inverted toward the opposite direction before they collide with the inspected sample 104. Electrons reflected off the sample become the mirror electrons 100c.

The mirror electron imaging optical system is explained. The mirror electrons 100c form a first image by the objective lens 106. Because the separator 103 is the E×B deflector in the present embodiment, it can be controlled not to produce an effect of deflecting an electron proceeding upward, and the mirror electrons 100c advance straight in the direction of the upright imaging electron column, and the first image is formed sequentially by an intermediate electronic lens 111 and a projection electronic lens 112. These intermediate lens 111 and projection lens 112 are an electrostatic or magnetic lens. A final electron image is magnified and projected by an image detecting section 116. Details of the image detecting section 116 are mentioned below. While the projection electron lens 112 is drawn as one electronic lens in FIG. 1, it includes a plurality of electron lenses or multipoles for the purpose of a higher magnification, correction of image distortion, or the like, in some cases. Although not drawn in this figure, a deflector, an astigmatism corrector, and the like for more specific adjustments in electron optics are mounted as necessary.

The ultraviolet-ray emitting section is explained. An ultraviolet ray from an ultraviolet ray light source 113 is monochromatized by a monochromator 114, and is emitted onto the inspected sample 104 by an ultraviolet ray optical element 115. Because the inspected sample 104 is held in a vacuum, a space is divided into an atmospheric side and a vacuum side by a window created with a material (e.g. quartz, etc.) that transmits ultraviolet rays, and an ultraviolet ray emitted from the ultraviolet ray optical element 115 is emitted through the window. Alternatively, the ultraviolet ray light source 113 may be installed in the vacuum. In that case, it is also possible to use a solid element or the like having a particular light-emission wavelength as an ultraviolet ray light source, instead of using wavelength selection by the monochromator 114. The illumination wavelength of the ultraviolet ray is a wavelength corresponding to energy higher than the bandgap of the material of the sample. Alternatively, depending on the state of energy levels in the bandgap of the material, a wavelength of energy smaller than the bandgap energy is selected as a wavelength to generate carriers in the sample material, in some cases. The ultraviolet ray light source 113, the monochromator 114, and the ultraviolet ray optical element 115 are connected by optical fibers and the like, and the ultraviolet ray is transferred therethrough. Alternatively, the ultraviolet ray light source 113 and the monochromator 114 may have an integrated configuration. In addition, in a case that the ultraviolet ray light source 113 can include a filter that transmits only a wavelength within a particular range, the monochromator 114 is not used in some cases.

The image detecting section 116 of the mirror electron imaging optical system mentioned before converts an image of the mirror electrons 100c into electric signals, and sends the electric signals to an inspection device control section 117. The image detecting section 116 includes, as an example, a fluorescent plate that converts electrons into visible light, and a camera that images an electron image of the fluorescent plate, includes, as another example, a two-dimensional detector such as a CCD element that detects electrons, and so on. A mechanism that amplifies the intensity an electron image or the intensity of fluorescence may also be included.

A mirror electron image of each location on the surface of the sample 104 is output from the image detecting section 116 while the moving stage 108 is being driven. The moving stage 108 is stopped when each image is imaged, or keeps moving at a constant speed without stopping when each image is imaged.

Operating conditions of various device sections including the condition of the imaging operation described above are input to and output from the inspection device control section 117. Various conditions such as an acceleration voltage at the time of generation of an electron beam, a stage moving speed, timings to acquire image signals from an image detecting element or ultraviolet ray emission conditions are input to the inspection device control section 117 in advance, and the inspection device control section 117 comprehensively controls the moving-stage control device 107, an electron optical system control device 118 that controls each electron optical element, the control system of the ultraviolet ray light source 113 and the monochromator 114, and the like. In some cases, the inspection device control section 117 includes a plurality of computers that share the role of the inspection device control section 117, and are coupled by a communication line. In addition, an input/output device 119 with a monitor is installed, and can be used by a user for the adjustment of the inspection device, input of operating conditions, execution of inspections, and the like. A mirror electron image is automatically transferred from the input/output device 119 to an image processing device 120 through a LAN, is viewed or is converted into a different file format, and output to a file.

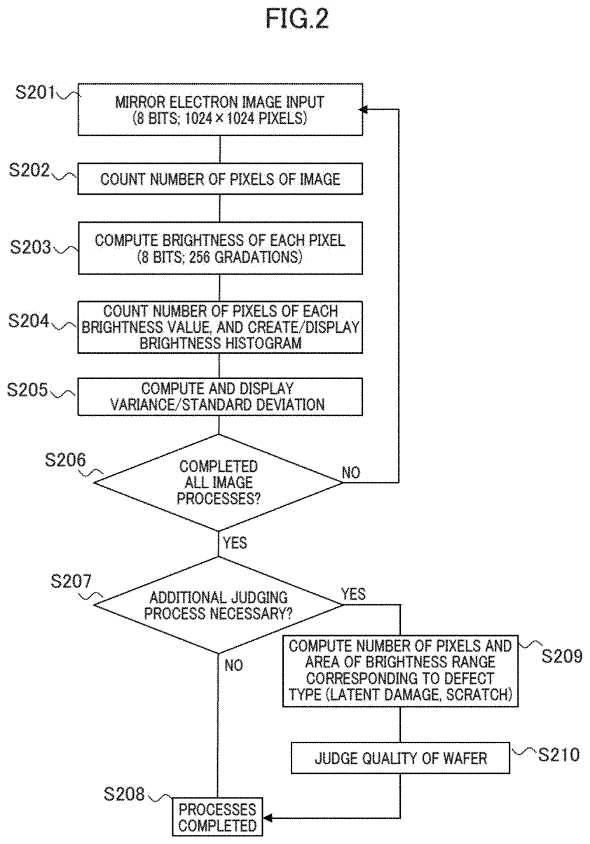

FIG. 2 illustrates a processing flow of quantification of a mirror electron image in the present embodiment. A mirror electron image with 1024×1024 eight-bit pixels transferred from the input/output device 119 is stored on a storage device in the image processing device 120 (Step, hereinafter, S201). Next, a processor of the image processing device 120 numerically obtains a brightness value of each pixel composing the image, counts the number of pixels with each brightness value of 256 gray levels, and stores a result thereof on the storage device (S202 and S203). Note that, although not illustrated in the flow diagram in FIG. 2, a brightness value to be a reference value is obtained in advance from a mirror electron image not having defects, or having defects only to a tolerable degree, and is stored on the storage device.

Next, in accordance with a command from software, the processor retrieves count data of the number of pixels of each brightness value from the storage device, and creates a histogram. The processor computes the variance and standard deviation of the histogram, and stores them on the storage device. The processor displays the variance or standard deviation, which is statistical data of a mirror electron image stored on the storage device, on a display device (S204 and S205). It is also possible to perform a similar process on both the reference brightness values, and the brightness values of the inspected sample, and display processing results of the reference and the inspected sample on the display device together. Other than displaying on the display device, they may be output via an external medium. Note that it is also possible to calculate the standard deviation or the variance directly from the brightness values without going through the histogram creation process. In a case that the entire image processing is completed (S206: Yes), and a further additional judgment process is not necessary (S207: No), the process is completed (S208). Note that the additional judgment process (S209 to S210) that is to be performed in a case that the additional judgment process is necessary at S207 is explained in the third embodiment.

Next, the principle of the formation of the mirror electron image obtained by the mirror electron microscope is explained. The mirror electron image visualizes the electrostatic potential over the sample surface, and has white/black contrast depending on the shape of the potential. For example, in a case that there is a concave defect like a scratch on the sample surface, the equipotential surface also presents a concave shape. Because of this, mirror electrons that are reflected at the concave section gather toward the electron optical axis. Accordingly, the density of the electrons becomes high at the center of the objective plane of the lens, and bright contrast is formed. On the other hand, a damage that is present inside a crystal like a latent damage in a SiC wafer or the like creates the potential with a convex shape due to charged electrons (in a case that n-type impurities are doped) at the defect section due to ultraviolet light illumination. Because of this, mirror electrons that are reflected at the convex section are scattered toward the outer side of the optical axis. Accordingly, the density of the electrons at the center of the objective plane of the lens becomes low, and dark contrast is formed. The same principle applies also to convex defects, other than latent damages. In a case of a wafer doped with p-type impurities, contrast which is opposite to that in the case of n-type impurities is formed.

In inspections with a defect inspection device that uses a mirror electron microscope, bare wafers before circuit patterns of power devices are formed are often inspection targets. This is for making use of an advantage of the microscope that crystal defects inside wafers can be detected at high sensitivity by ultraviolet ray illumination.

Next, an implementation method of a defect inspection according to the present embodiment is explained. SiC is supposed to be a sample in the explanation. SiC wafers are sliced out from an ingot of SiC by a method such as wire sawing. The wafers are ground and finished their surfaces by CMP process. Next, mirror electron images of these wafers are acquired by the mirror electron microscope. Note that images are acquired by the mirror electron microscope after performing oxygen cleaning on the SiC wafers in some cases. In the mirror electron microscope that performs defect detection on the basis of electric potential differences, carbonaceous contaminations on the SiC wafers adsorbed in the atmospheric air lead to accumulation/leakage of charges, and so it is possible to perform inspections at high sensitivity by performing imaging by the mirror electron microscope after eliminating the contaminations by oxygen cleaning in advance.

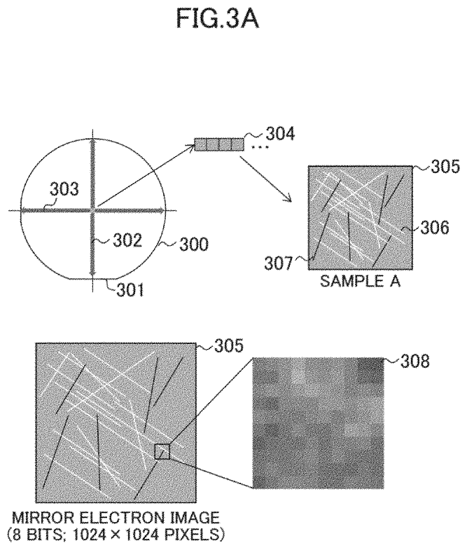

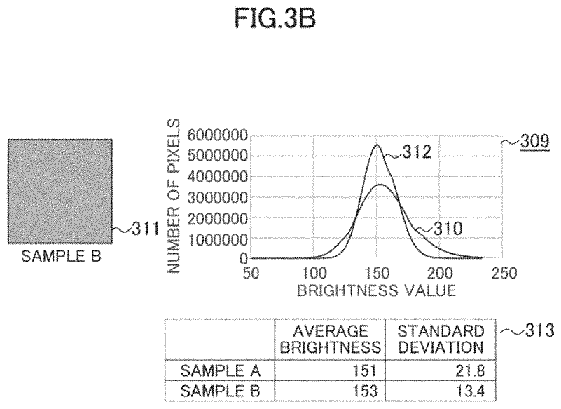

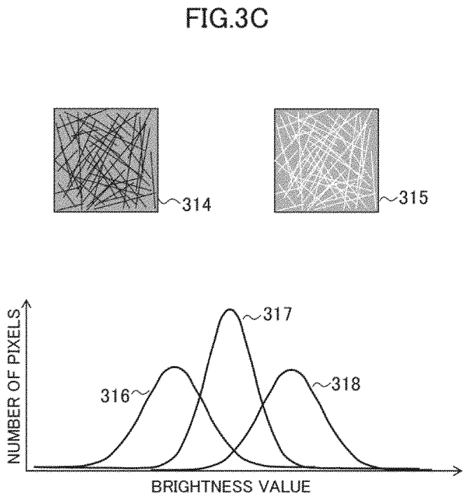

FIG. 3A and FIG. 3B illustrate an imaging method performed by the mirror electron microscope according to the present embodiment. The center of a wafer 300 is defined as the origin. The direction perpendicular to the orientation flat 301 is defined as the direction 302, and the direction parallel to the orientation flat 301 is defined as the direction 303. In four directions along the direction 302 and the direction 303 from the center, the wafer stage steps at intervals of 70 μm to implement consecutive imaging 304, and FOV-unit mirror electron images 305 are acquired. Particularly, in the processes of grinding and CMP, the wafer is being rotated during the processes, and the defects generated by the processes have concentric distributions in many cases. In view of this, it is preferable to perform imaging from the center toward the outside direction for the purpose of more efficiently inspecting the tendency of process damages on the wafer surface. While imaging is performed in four directions from the center as illustrated in FIG. 3A in the present embodiment, the number of images may be increased by increasing the number of directions to eight or twelve, and so on in a case that there are few damages caused by processing and the quality judgment of wafers is difficult.

Obtained mirror electron images visualize, as contrast, process damages generated by grinding and CMP polishing. In a case that scratches (physical concavities) are generated on a wafer, bright linear contrast 306 is formed. The brightness value of the pixels is approximately 180 to 220, for example. In a case that latent damages, which are crystal damages inside a wafer, are generated, dark linear contrast 307 is formed. The brightness value of the pixels is approximately 50 to 80, for example. The brightness value of background pixels of a mirror electron image with no defects like a sample B is supposed to be approximately 150 to 160 as illustrated in FIG. 3B. Brightness values of an image of a sample which has a satisfactory quality not having defects or having defects only to a tolerable degree like the sample B are stored in advance on the storage device as a reference. In the present embodiment, a mirror electron image is converted into a grayscale image with 1024×1024 eight-bit unit pixels 308, and the grayscale image is output from the device.

Next, the mirror electron image 305 is input to the image processing device 120, and quantified. Because the image is an eight-bit image, the brightness value of each pixel is expressed by 256 gradations as mentioned above. The brightness value of each pixel is determined, and a brightness histogram (frequency distribution) 309 on which the brightness value is represented along the horizontal axis, and the number of pixels is represented along the vertical axis is created.

Two histograms are drawn in the brightness histogram 309 in FIG. 3B. Those are a histogram 310 of a sample A on which scratches and latent damages are confirmed over the entire surface of a mirror electron image, and a histogram 312 of a satisfactory sample B 311 without latent damages and scratches as a reference.

The horizontal axis of the histograms represents the brightness value of each pixel. Because the number of pixels with brightness values higher than the average value is large in the histogram with many scratches, the histogram has a shape that is wider on the right side (on the side of higher brightness values) as compared to 312. Similarly, because the number of pixels with brightness values lower than the average value is large in the histogram of the mirror electron image with many latent damages, the histogram has a shape that is wider on the left side (on the side of lower brightness values) as compared to 312. As a result, the half width of the histogram 310 of the sample having many defects such as scratches or latent damages that produce different brightness values becomes wider as compared with the histogram 312 of the mirror electron image in the satisfactory state to be the reference (FIG. 3B).

It is desired in some cases to perform comparison with the reference by using an evaluation value which is stricter than histograms, and to judge whether the quality of a wafer is good or bad. In this case, as an indicator of variations of the brightness histograms of the mirror electron microscope images, a standard deviation 313 is used in the present embodiment. According to the result here, the standard deviation value of the image of the sample A with many scratches is a value which is larger approximately by eight as compared with the sample B to be the reference. The standard deviation of the mirror electron image of the sample A with many defects is larger than the standard deviation of the sample B with no defects, and the quality judgment can be performed simply without visually checking images. Note that other than standard deviations, a typical statistics technique such as the half width of a histogram, a coefficient of fluctuation, or the half width in the Lorentz distribution may be used for numerical expression.

FIG. 3C shows how brightness histograms change depending on the total number of defects, or differences between the amounts of different defect types. A mirror electron image 311 to be a reference with no defects has entirely no contrast. The peak of the histogram 317 is around the center of the horizontal axis in this graph in which the vertical axis represents the number of pixels and the horizontal axis represents brightness values. On the other hand, in a histogram of an image 314 with many latent damages, the peak position of the histogram 316 shifts toward the direction of low brightness values, and the shape becomes horizontally wider. Similarly, the histogram 318 of the image 315 with many scratches has a horizontally wider shape, and the peak position shifts toward the direction of high brightness values. Due to histograms being horizontally wider because of latent damages and scratches, the half widths, variances or standard deviation values of the histograms become larger than those in the case of the mirror electron image 317 to be the reference with no defects. In this manner, on the basis of brightness histograms, or standard deviations, variances or the like computed from the brightness histograms, it is possible to judge whether which of defect types with different brightness, for example scratches and latent damages, are present in a large amount.

Such a judgment may be made by a user on the basis of histograms obtained from mirror electron images of the reference and an inspected wafer displayed on a display device, or may be made by the image processing device 120 of the mirror electron microscope by comparing the histogram of the reference, and the histogram of the inspected wafer, calculating the degree of deviation from the reference, and outputting a judgment result on the basis of the degree of deviation. Here, the degree of deviation means both how largely the peak position shifts toward higher or lower brightness relative to the reference, and how wide the half width of the histogram (including a case that variations are determined strictly by a statistical process such as a standard deviation or a variance) is relative to the reference.

While, in the present embodiment mentioned above, a mirror electron image imaging latent damages and scratches that are present on a SiC wafer after grinding and CMP is quantified, defect contrast that occurs due to basal plane dislocation, stacking faults or foreign matters can also be processed similarly. In addition, quantification is similarly possible also for a SiC wafer on which an epitaxial layer is formed. Note that while a SiC wafer is explained as the sample in the present embodiment, the sample may be a Si wafer or a GaN substrate, and is not limited to SiC.

According to the present embodiment, the brightness values of all the pixels composing a mirror electron image are counted, and a standard deviation value computed from the histogram thereof is used as an indicator for a judgment as to whether the quality of a wafer is good or bad. It is possible thereby to display the defect contrast on the mirror electron image quantitatively, ambiguity that results from qualitative evaluation is eliminated by automation of the judgment, and this contributes to the stabilization of the evaluation quality.

### Second Embodiment

In the second embodiment, for the standard deviation value of the brightness histogram of a mirror electron image computed in the first embodiment, an operator sets a threshold of standard deviation values via the input/output device 119, and, in a case that there are n or more mirror electron images (n is a natural number) having standard deviation values exceeding the threshold, the sample is judged as a bad product. That is, the second embodiment describes a defect inspection device and method in which, in a case that there are n or more FOV-unit mirror electron images having standard deviation values of brightness histograms exceeding a preset threshold, the image processing device 120 judges that the sample is of bad quality.

The threshold of standard deviation values, and the number n about mirror electron images having standard deviations values exceeding the threshold are set in advance in the image processing device 120 via the input/output device 119 of the mirror electron microscope in FIG. 1 by an operator. Thereby, it is possible to automatically perform sample quality judgments from mirror electron images acquired by the mirror electron microscope.

### Third Embodiment

While sample quality judgments are performed by determining standard deviations from brightness histograms of mirror electron images in the methods explained in the first embodiment and the second embodiment, a sample quality judgment is performed by counting brightness values of pixels of a mirror electron image in the third embodiment. That is, the third embodiment describes a defect inspection device and method in which the image processing device 120 counts brightness values of pixels of the mirror electron image, and performs a quality judgment of the sample on the basis of the number of pixels that have brightness values exceeding a preset brightness threshold.

In the present embodiment, the image processing device 120 determines the brightness value of each pixel composing a mirror electron image, and the number of pixels, and uses preset brightness thresholds and number of pixels as a basis to perform a sample quality judgment. The brightness thresholds used determine upper and lower brightness thresholds corresponding to the brightness value for scratches, approximately 180 to 220 in the case illustrated before, and the brightness values for latent damages, approximately 50 to 80 in the case illustrated before. The number of pixels and area within the brightness range are computed (S209 in FIG. 2), and the sample quality judgment is performed on the basis of results of the computation (S210).

In this manner, in the present embodiment, because the brightness values of pixels of a mirror electron image are counted, it is possible to determine whether there is more significant bright contrast of scratches or more significant dark contrast of latent damages on the mirror electron image, and it is possible to simply evaluate the tendency of sample processing damages. Note that instead of the method mentioned above, the image processing device 120 may provide a threshold for the brightness values of pixels, compute the area from the total number of pixels having brightness values exceeding the threshold, and perform a quality judgment on the basis of the area ratio of the area to the total area of the acquired image.

### Fourth Embodiment

The present embodiment describes a judgment method of the quality of mirror electron images for wider area than the FOV, and the mirror electron optical system performs wide-range imaging by imaging a plurality of two-dimensionally consecutive FOV-unit mirror electron images. The image processing device 120 uses the plurality of mirror electron images to generate a tiling image. The fourth embodiment describes a defect inspection device and method in which the image processing device 120 computes the standard deviation value of the brightness of each FOV-unit mirror electron image, and outputs the computed standard deviation values as a two-dimensional matrix.

In the present embodiment also, similarly to the first embodiment, a wafer is supposed to have ground and CMP-processed surface. Wide-range imaging of the sample is performed by the mirror electron microscope to acquire mirror electron images.

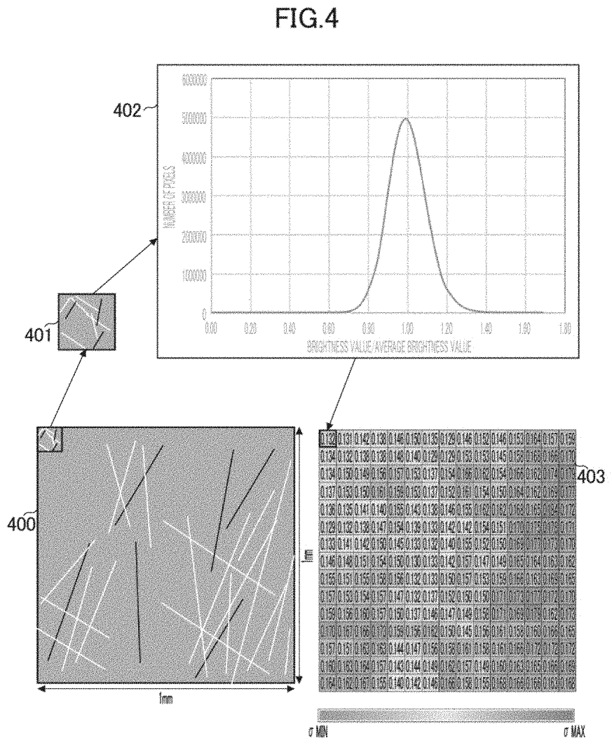

FIG. 4 illustrates acquisition of mirror electron images for the wide range according to the present embodiment. Here the wide-range image consists of consecutively acquired FOV-sized images for an area of 1 mm×1 mm centered at particular coordinate of the wafer. For example, the wide-range imaging is performed for 10,000 positions per sample. It is supposed here that one FOV-unit mirror electron image has an area of 80 μm×80 μm. In the wide-range imaging, the image processing device 120 places mirror electron images next to each other such that the mirror electron images match their imaging position coordinates, and creates a tiling image 400 which is a 1-mm×1-mm mirror electron image of the wide-range imaging. This tiling image 400 is filled with the FOV-unit mirror electron images 305 of 225 shots, and the mirror electron images 305 are aligned relative to each other on a plane.

Furthermore, in the present embodiment, the image processing device 120 creates a brightness histogram 402 by the method explained in the first embodiment for each FOV-unit mirror electron image 401, determines the standard deviation values of the 225 mirror electron images, arranges them on a matrix, and creates a brightness standard deviation plot 403. In the present embodiment, a conditional formatting functionality of spread sheet software or the like is used to display the standard deviation values of the images on a display device in different colors.

Because the mirror electron images are output as grayscale images as illustrated in FIG. 3A, the state of the distribution of process damages is difficult to determine visually when a wide range is imaged; however, as illustrated in FIG. 4, by using different colors for the display, on the display device, on the basis of the mirror electron images of the wide-range imaging in the present embodiment, it is possible to visually and simply determine that the right side of the imaged area has large standard deviation values due to scratches, and the upper left portion has low standard deviation values, and has fewer scratches.

By combining various embodiments explained above, a more highly reliable defect inspection device can be provided. The present invention is not limited to the embodiments described above, but includes various modification examples. For example, the embodiments described above are explained in detail for better understanding of the present invention, and are not necessarily limited to those including all the configurations explained.

Furthermore, although individual configurations, functionalities, judging sections, various types of control, image processing devices and the like mentioned above are explained mainly about an example in which a program of a processor that realizes some or all of them is created, it is needless to say that some or all of them may be realized by hardware by designing them on an integrated circuit or by other means, for example. That is, all or some of functionalities of the image processing device may be realized by an integrated circuit such as an ASIC (Application Specific Integrated Circuit) or a FPGA (Field Programmable Gate Array), or the like, for example, instead of a program.

### LIST OF REFERENCE SIGNS

101: Electron gun
102: Condenser lens
103: Separator
104: Inspected sample (wafer)
105: Electron-gun control device
106: Objective lens
107: Moving-stage control device
108: Moving stage
109: Sample holder
110: High-voltage power supply
111: Intermediate electronic lens
112: Projection electronic lens
113: Ultraviolet ray light source
114: Monochromator
115: Ultraviolet ray optical element
116: Image detecting section
117: Inspection device control section
118: Electro-optical-system control device
119: Input/output device
120: Image processing device
300: Inspection wafer
301: Orientation flat
302: Vertical imaging
303: Horizontal imaging
304: Consecutive imaging
305: FOV-unit mirror electron image
306: Scratches on mirror electron image
307: Latent damages on mirror electron image
308: Unit pixel of mirror electron image
309, 401: Brightness histogram
310: Histogram on which latent damages and scratches are confirmed on mirror electron image
311, 317: Image diagram of mirror electron image with no defects
312: Brightness histogram of mirror electron image with no defects
313: Standard deviation value
314: Image diagram of mirror electron image with many latent damages
315 Image diagram of mirror electron image with many scratches
316: Brightness histogram of mirror electron image with many latent damages
318: Brightness histogram of mirror electron image with many scratches
400: Tiling image
402: Brightness histogram
403: Brightness standard deviation plot

1. A defect inspection device comprising:
an electron optical system that irradiates a sample with electrons emitted from an electron source;
a mirror electron imaging optical system that forms an image of mirror electrons reflected before the electrons reach the sample due to application of a voltage to the sample, and acquires a mirror electron image;
an ultraviolet-ray emitting section that irradiates a range including an irradiation range of the electrons with an ultraviolet ray during the irradiation with the electrons;
an image processing device that performs a calculation process on the acquired mirror electron image, and outputs a result of the calculation process; and
a display device, wherein
the image processing device converts the mirror electron image into brightness values, and generates a reference, and an inspection result of the sample, and
the display device displays the reference and the inspection result together.

2. The defect inspection device according to claim 1, wherein
the image processing device generates the reference and the inspection result on histograms, and
a degree of deviation between the histogram of the reference and the histogram of the inspection result is computed.

3. The defect inspection device according to claim 1, wherein the image processing device computes standard deviation values or variance values of a brightness value of the reference, and a brightness value of the sample.

4. The defect inspection device according to claim 3, wherein, in a case that the standard deviation value or variance of the inspection result is higher than the standard deviation value or variance value of the reference, it is judged that the sample has more defects than the reference does.

5. The defect inspection device according to claim 3, wherein, in a case that there are n or more mirror electron images (n is a natural number) each having the standard deviation value exceeding a threshold in the sample, the image processing device judges that the sample is of bad quality.

6. The defect inspection device according to claim 1, wherein the image processing device counts brightness values of pixels of the mirror electron image, and performs a quality judgment of the sample on a basis of the number of pixels that have brightness values exceeding a preset brightness threshold.

7. The defect inspection device according to claim 6, wherein the image processing device computes an area from a total of the number of pixels that have brightness values exceeding the brightness threshold, and performs a quality judgment of the sample on a basis of an area ratio of the area to a total area of the acquired mirror electron image.

8. The defect inspection device according to claim 1, wherein
the mirror-electron imaging optical system is used to perform wide-range imaging of imaging a plurality of two-dimensionally consecutive mirror electron images, and acquire a tiling image, and
the image processing device computes a standard deviation value of a brightness of each FOV-unit mirror electron image in the tiling image, and outputs the computed standard deviation values as a two-dimensional matrix.

9. The defect inspection device according to claim 8, wherein the display device displays, in different colors, the standard deviation values output by the image processing device.

10. A defect inspection method for a sample, the defect inspection method comprising:
while electrons emitted from an electron source are being illuminated onto the sample, illuminating an ultraviolet ray onto a range including an irradiation range of the electrons;
forming an image of mirror electrons that are reflected before the electrons reach the sample due to application of a voltage to the sample, and acquiring a mirror electron image; and
converting the mirror electron image into brightness values, and generating a reference histogram, and an inspection result histogram of the sample.

11. The defect inspection method according to claim 10, comprising starting an inspection after oxygen cleaning is performed on the sample in advance.

12. The defect inspection method according to claim 10, comprising: performing imaging from a sample center of the sample toward one or more radial directions, and acquiring the mirror electron image.

13. The defect inspection method according to claim 10, comprising: judging that the sample has more concave defects than the reference does in a case that a brightness value of a peak of the inspection result histogram is in a region higher than a brightness value of a peak of the histogram of the reference, and judging that the sample has more latent damages or convex defects than the reference does in a case that the brightness value of the peak of the inspection result histogram is in a region lower than the brightness value of the peak of the histogram of the reference.

14. The defect inspection method according to claim 12, comprising: judging that the sample has more defects than the reference does in a case that the number of pixels of a peak of the inspection result histogram is in a region lower than the number of pixels of a peak of the histogram of the reference.
